(19) United States
(12) Patent Application Publication
(10) Pub. No.: US 2014/0110089 A1
(43) Pub. Date: Apr. 24, 2014

(54) AIR DUCT AND HEAT DISSIPATION SYSTEM HAVING THE SAME

(71) Applicant: TAI-WEI LIN, Tu-Cheng (TW)

(72) Inventor: TAI-WEI LIN, Tu-Cheng (TW)

(21) Appl. No.: 13/663,490

(22) Filed: Oct. 30, 2012

(30) Foreign Application Priority Data
Oct. 22, 2012 (TW) 101138935

(51) Int. Cl. H01L 23/467; F16L 9/00

(52) U.S. Cl. 165/121; 138/177

(57) ABSTRACT

An air duct includes two spaced sidewalls, a top wall connected between tops of the sidewalls, an extension plate pivotably mounted between tops of the sidewalls in front of the top wall, and a deformable portion to maintain the extension plate coplanar with the top wall.

### BACKGROUND

1. Technical Field

The present disclosure relates to a heat dissipation system including an air duct.

2. Description of Related Art

For an air duct, a space is often provided between tops of the air duct and a fan, for a user to extend a hand through to handle the fan. As a result, airflow from the fan may flow out of the air duct through the space, which will reduce the heat dissipation efficiency.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a first exemplary embodiment of a heat dissipation system.

FIG. 2 is an assembled, isometric view of FIG. 1.

FIG. 3 is an assembled, isometric view of a second exemplary embodiment of a heat dissipation system.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

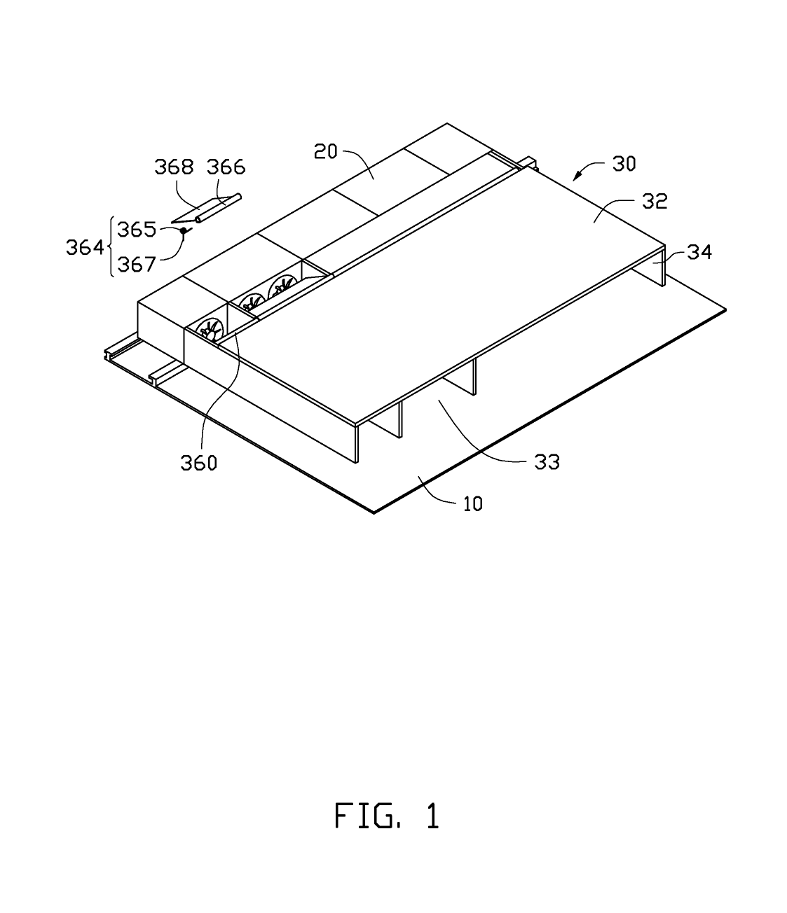

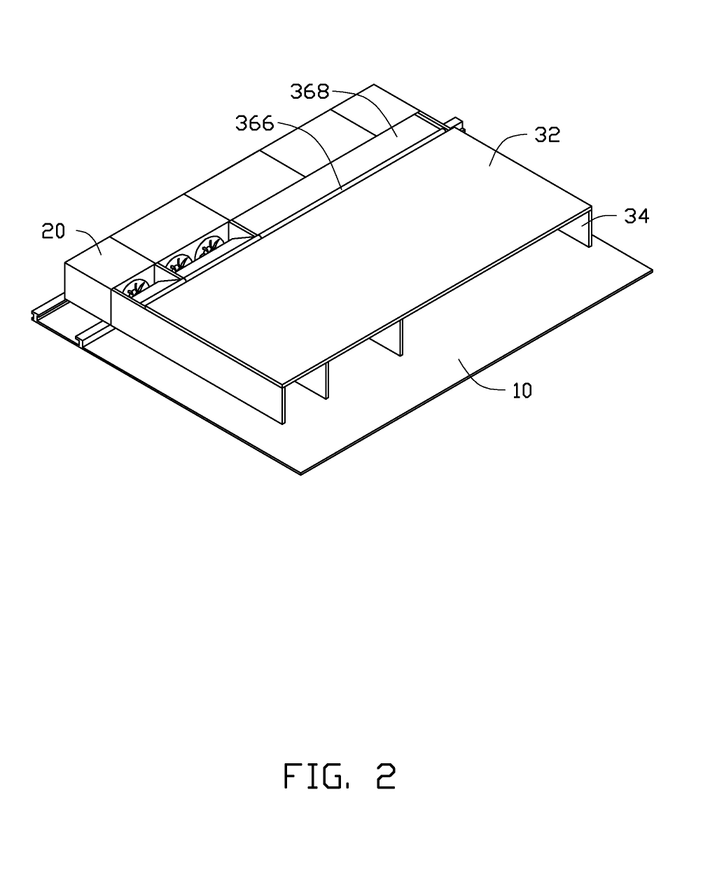

FIGS. 1 and 2 shows an exemplary embodiment of a heat dissipation system. The heat dissipation system include a base board 10, an air duct 30 mounted on the base board 10, and a row of fans 20 mounted on the base board 10 and positioned adjacent to a front side of the air duct 30.

The air duct 30 includes a plurality of spaced side boards 34 perpendicularly rested on the base board 10, a top board 32 perpendicularly mounted on tops of the side boards 34 opposite to the base board 10, a plurality of poles 360 each connected between two adjacent side boards 34 and in front of the top board 32, a plurality of extension boards 368 rotatably mounted to the poles 360, and a plurality of maintaining elements 364. An airflow channel 33 aligning with one of the fans 29 bound by every two adjacent side boards 34, the base board 10, and the top board 32. In this embodiment, the maintaining elements 364 are torsion springs each including a coiled main body 365 fitted about one of the poles 360 and two legs 367 extending away from each other from opposite ends of the main body 365. A hollow installation portion 366 extends from a side of each extension board 368 to fit about one of the poles 360, thereby rotatably installing the extension board 368 to the pole 360. The legs 367 of each torsion spring 364 are respectively abutted to an inner surface of the portion 366 and the top board 32, to maintain the extension board 368 coplanar with the top board 32, thereby covering a space between the top board 32 and a corresponding one of the fans 20. The extension boards 368 are capable of being pivoted upward or downward to deform the torsion springs 364, thereby exposing the spaces to detach the fans 20. The extension boards 368 are then released, and the torsion springs 364 are restored to maintain the extension boards 368 coplanar with the top board 32.

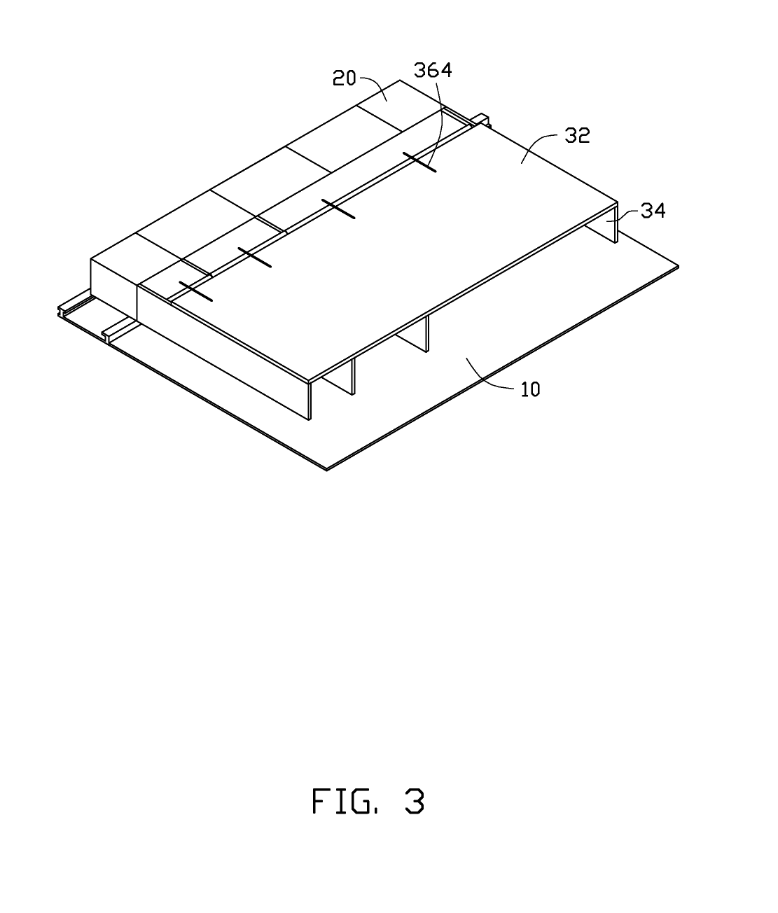

FIG. 3 shows in another embodiment, the maintaining elements 364 are elastic lines or belts. Opposite ends of each flexible line are respectively fixed to a top of the top board 32 and an outer surface of a corresponding one of the extension boards 368; thereby maintaining the extension board 368 coplanar with the top board 32 to cover the space between the top board 32 and a corresponding one of the fans 20. At this time, the extension boards 368 can be pivoted upward to expose the spaces. When the extension boards 368 are released, the extension boards 368 drops downward until the flexible line is stretched.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An air duct, comprising:
two opposite side boards;
a top board mounted to top sides of the side boards;
an extension board mounted between the top sides of the side boards and in front of the top board; and
a maintaining element maintaining the extension board coplanar with the top board.

2. The air duct of claim 1, further comprising a pole connected between the top sides of the side boards and in front of the top board, wherein the extension board comprises a hollow installation portion rotatably fitted around the pole.

3. The air duct of claim 2, wherein the maintaining element is a torsion spring comprising a coiled main body fitted about the pole and two legs extending from opposite ends of the main body and respectively abutting an inner surface of the installation portion and the top board.

4. The air duct of claim 1, wherein the maintaining element is an elastic line opposite ends of which are fixed to tops of the top board and the extension board.

5. A heat dissipation system, comprising:
a base board;
an air duct comprising two opposite side boards perpendicularly fixed on the base board, a top board mounted to rear top sides of the side boards opposite to the base board, an extension board mounted between the top sides of the side boards and in front of the top board, and a maintaining element maintaining the extension board coplanar with the top board; and
a fan mounted on the base board and in front of the air duct;
wherein the extension board covers a space between the fan and the air duct.

6. The heat dissipation system claim 5, further comprising a pole connected between the top sides of the side boards and in front of the top board, wherein the extension board comprises a hollow installation portion rotatably fitted around the pole.

7. The heat dissipation system of claim 6, wherein the maintaining element is a torsion spring comprising a coiled main body fitted about the pole and two legs extending from opposite ends of the main body and respectively abutting an inner surface of the installation portion and the top board.

8. The heat dissipation system of claim 5, wherein the maintaining element is an elastic line opposite ends of which are fixed to tops of the top board and the extension board.
